(19) United States
(12) Patent Application Publication
(10) Pub. No.: US 2007/0215336 A1
(43) Pub. Date: Sep. 20, 2007

(54) Mesh-type heat dissipating structure

(75) Inventor: I-Che Hsu, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/378,831

(22) Filed: Mar. 17, 2006

(51) Int. Cl. H05K 7/20

(52) U.S. Cl. 165/185; 165/80.3; 361/704; 257/722

(57) ABSTRACT

A mesh-type heat dissipating structure includes a base and a plurality of heat dissipating fins disposed at intervals on the base, each of the heat dissipating fins having a plurality of meshes to increase the heat dissipating area of the heat dissipating structure, such that the mesh-type heat dissipating structure can increase the heat dissipating efficiency effectively.

### FIELD OF THE INVENTION

The present invention relates to heat dissipating structures, and more particularly, to a heat dissipating structure applied in an electronic device to dissipate heat.

### BACKGROUND OF THE INVENTION

A conventional heat dissipating structure provided in a desktop computer or a laptop computer normally comprises a base and a plurality of rectangular fins disposed on the base, and mostly the base and the fins are integrally formed. Such heat dissipating structure has significant drawbacks, for example, insufficient heat dissipating area, relatively heavier weight, and low degree of mixing of heat exchange between airflow and heat in an airflow path formed between the fins, thereby resulting in an unsatisfactory heat dissipating efficiency. Moreover, the airflow in the airflow path formed between the fins does not have kinetic energy supply, making the airflow speed reduced at a later part of the airflow path and affecting the heat dissipating efficiency.

Therefore, the problem to be solved here is to provide a heat dissipating structure for effectively increasing the heat dissipating efficiency, which has a relatively lighter weight as compared with the conventional one made of the same material.

### SUMMARY OF THE INVENTION

In light of the above drawbacks of the prior art, an objective of the present invention is to provide a heat dissipating structure to effectively increase the heat dissipating efficiency.

Another objective of the present invention is to provide a mesh-type heat dissipating structure having increased heat dissipating area and reduced weight.

In accordance with the above and other objectives, the present invention provides a mesh-type heat dissipating structure, comprising a base and a plurality of heat dissipating fins disposed at intervals on the base, each of the heat dissipating fins having a plurality of meshes for allowing air to flow through the meshes.

In a preferred embodiment, the base is formed with a plurality of positioning grooves on a surface thereof, wherein the positioning grooves are arranged at intervals and in an oblique manner relative to edges of the surface of the base. The positioning grooves are formed of fixing members engaged with the base, the fixing members having recessed grooves, so as to allow the heat dissipating fins to be coupled to the fixing members and assembled to the base. By provision of the plurality of meshes of the heat dissipating fins, it can effectively overcome the drawbacks in the prior art, such as low degree of mixing of heat exchange between airflow and heat in an airflow path formed between fins, reduced airflow speed at a later part of the airflow path formed between the fins due to not providing kinetic energy supply for the airflow, insufficient heat dissipating area, and relatively heavier weight. Therefore, the heat dissipating structure of the present invention can increase the heat dissipating efficiency when the heat dissipating structure is applied in the electronic device.

### BRIEF DESCRIPTION OF THE DRAWINGS

The present invention can be more fully understood by reading the following detailed description of the preferred embodiments, with reference made to the accompanying drawings, wherein:

FIG. 1 is a perspective view of a mesh-type heat dissipating structure according to a preferred embodiment of the present invention; and

FIG. 2 is a perspective view of a base of the mesh-type heat dissipating structure according to the present invention.

### DETAILED DESCRIPTION OF THE PREFERRED EMBODIMENT

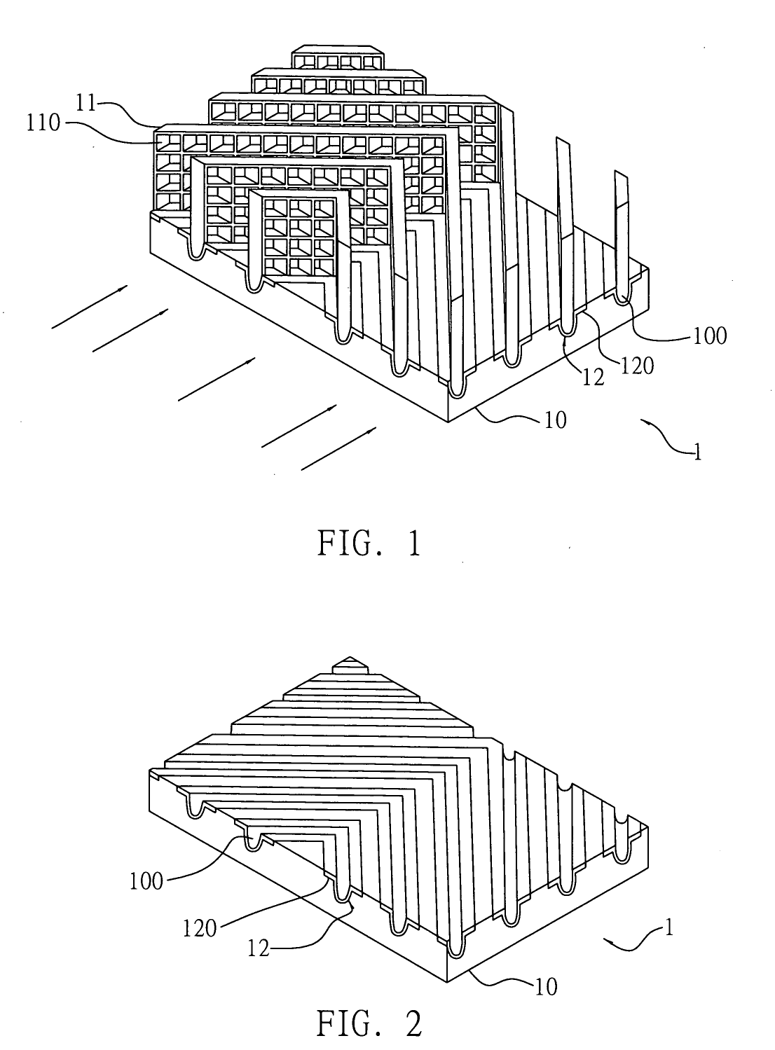

The preferred embodiment of a mesh-type heat dissipating structure proposed in the present invention is described as follows with reference to FIGS. 1 and 2. It is to be noted that the drawings are simplified schematic diagrams and only show components relating to the present invention. In practice, the layout of components could be more complicated. It should be understood that the following embodiment is not construed to limit the scope of the present invention.

As shown in FIGS. 1 and 2, a mesh-type heat dissipating structure 1 of the present invention comprises a base 10 and a plurality of heat dissipating fins 11 vertically disposed at intervals on the base 10, wherein each of the heat dissipating fins 11 has a plurality of meshes 110.

The base 10 has a plurality of positioning grooves 100 on a surface thereof, for positioning the heat dissipating fins 11. The positioning grooves 100 are arranged at intervals and in an oblique manner relative to edges of the surface of the base 10. The positioning grooves 100 are formed of the fixing members 12 engaged with the base 10, wherein each of the fixing members 12 has a recessed groove and is formed with flanges 120 on two sides thereof. The plurality of heat dissipating fins 11 together with the meshes 110 thereof are arranged in a manner to provide an array of airflow paths for air to flow therethrough.

In this embodiment, during operation, arrows shown in FIG. 1 point to input of air to the surface of the base 10 having the positioning grooves 100, and with the array of airflow paths provided by the arrangement of the plurality of heat dissipating fins 11 together with the meshes 110 thereof, the airflow input to the surface of the base 10 can be exempted from suffering the problems as in the prior art, such as low degree of mixing of heat exchange between airflow and heat in an airflow path formed between fins, and reduced airflow speed at a later part of the airflow path formed between the fins due to not providing kinetic energy supply for the airflow. The mesh-type heat dissipating structure 1 of the present invention using the plurality of heat dissipating fins 11 with the meshes 110 has increased heat dissipating area and reduced weight, thereby eliminating the drawbacks in the prior art, such as insufficient heat dissipating area, and relatively heavier weight. Therefore, the heat dissipating structure 1 of the present invention can increase the heat dissipating efficiency when the heat dissipating structure 1 is applied in the electronic device.

The present invention has been described using exemplary preferred embodiments above, however, it is to be understood that the scope of the present invention is not limited to the disclosed embodiments. On the contrary, it is intended to cover various modifications and similar changes. The scope of the claims, therefore, should be accorded the broadest interpretation so as to encompass all such modifications and similar arrangements.

What is claimed is:

1. A mesh-type heat dissipating structure comprising:
a base; and
a plurality of heat dissipating fins disposed at intervals on the base, each of the heat dissipating fins having a plurality of meshes for allowing air to flow through the meshes.

2. The mesh-type heat dissipating structure of claim 1, wherein the base has a plurality of positioning grooves for positioning the heat dissipating fins.

3. The mesh-type heat dissipating structure of claim 2, wherein the positioning grooves are formed of fixing members engaged with the base, the fixing members having recessed grooves.

4. The mesh-type heat dissipating structure of claim 3, wherein each of the fixing members has flanges on two sides thereof.

5. The mesh-type heat dissipating structure of claim 1, wherein the plurality of heat dissipating fins together with the meshes thereof are arranged in a manner to provide an array of airflow paths for the air to flow therethrough.
